(19) United States
(12) Patent Application Publication
(10) Pub. No.: US 2019/0288251 A1
(43) Pub. Date: Sep. 19, 2019

(54) Energy Storage System for Installation on Two- and Three- Dimensional Vertical Surfaces

(71) Applicant: Dieter Kurt Nowak, Winchester, TN (US)

(72) Inventors: Dieter K. Nowak, Winchester, TN (US); Werner Richard Nowak, Chattanooga, TN (US)

(73) Assignee: Micron Corporation, Winchester, TN (US)

(21) Appl. No.: 15/921,648

(22) Filed: Mar. 14, 2018

(51) Int. Cl. H01M 2/10; H05K 1/18; H01G 11/10; H01G 11/78; H01M 10/0525; H01M 10/0585

(52) U.S. Cl. CPC H01M 2/1077; H05K 1/181; H01G 11/10; H04B 1/04; H01M 10/0525; H01M 10/0585; H05K 2201/10098; H01G 11/78

(57) ABSTRACT

The invention concerns an energy storage system and method to install the energy storage elements, subsequently called “energy tiles”, of the system on solid or flexible, flat or curved surfaces of any orientation. Individual energy tiles are identical in size, capacity and voltage and shaped like ceramic tiles. They cover free surfaces by a combination of serially and parallel connected energy tiles. The installation produces a pattern similar to that of ceramic tiles. An energy tile can be a lithium battery or a supercapacitor cell. Candidates for the installation are wall surfaces of buildings, internal and external roof surfaces, the back side of solar panels, tents and internal and external vehicle surfaces. The storage elements are individually removable without disturbing the remaining energy tiles of the system.

### CROSS-REFERENCE TO RELATED APPLICATION

This application claims the benefit of U.S. Provisional Application No. 62/601,146, filed on Mar. 14, 2017.

### STATEMENT REGARDING FEDERALLY SPONSORED RESEARCH OR DEVELOPMENT

This invention was made with government support under contract W56HZV16C0144, awarded by the U.S. Department of Defense, Tactical Armament Command (TACOM). The government has certain rights in the invention.

### FIELD OF THE INVENTION

The presently disclosed subject matter is directed to energy storage systems. More specifically it is directed to energy storage systems which are part of the structure of buildings and vehicles such as walls, roofs, and vehicle surfaces.

### BACKGROUND OF THE INVENTION

Energy storage systems such as batteries for vehicles and back-up power systems in hospitals, factories and office buildings are usually installed in battery trays occupying floor space. In cases where additional energy storage is needed, or where the available floor space is too small or needed to store other equipment, floor space for energy storage installation might not be available.

Finding space for energy storage which is readily available but does not encroach on space that could be used for other equipment is therefore a difficult problem. This is in particular true in cases where tight space conditions already exist while additional energy storage to existing energy storage is needed, such as is the case in military vehicles.

This invention is based on a request for proposal by TACOM which is indicative of the scope of this invention and reads in part “to develop an innovative approach to incorporate additional energy storage into the vehicle by integrating batteries into the vehicle structure or armor without affecting personnel/platform survivability, safety, or operational performance and minimizing weight gain. Such a battery will be an integral part of the vehicle structure without encroaching into existing space claims. The design shall not merely package into existing unused space”.

In performing the contract W56HZV16C0144, the subject energy storage was expanded to include supercapacitor cells and modules as well as battery cells and modules. The combination of supercapacitors and batteries is generally known as a supercapacitor/battery hybrid, manufactured, for example, by Micron Corporation of Tennessee. The supercapacitor/battery hybrid has, in certain applications, well known advantages over batteries-only energy storage systems. This invention is therefore applicable to battery as well as supercapacitor cells.

In view of the space limitation problems associated with the installation of energy storage systems it would be highly desirable if an energy storage design was available which could be installed on structures that are widespread and common to all vehicles and buildings such as walls or vehicle surfaces. This would increase the number of options for packing energy storage into vehicles and commercial structures significantly, because free surfaces are generally readily available.

### BRIEF SUMMARY OF THE INVENTION

This invention concerns an energy storage system and a method to install the energy storing elements of the energy storage system on either a flat two dimensional or curved three dimensional surface having any orientation, including vertical or slanted. The invention eliminates the need to provide floor space and the trays needed to contain conventional energy storage elements. The invention increases the options for installing energy storage into vehicles and commercial structures by utilizing free surfaces which usually are plentiful available.

An energy storage system in accord with the present invention means an assembly of sealed lithium battery cells or supercapacitor cells referred to as energy storage elements, or beneficially, a suitable combination of both. The energy storage elements are in electrical contact with each other, in electrical contact with a charger and in electrical contact with a useful load. Each energy storage element is equipped with a low voltage and low power microprocessor based controller with an integrated radio frequency (RF) transmitter, a printed antenna on the circuit board and integrated electronic analog to digital conversion. The microprocessor gets its power from the energy storage element to which it is attached. The microprocessor based controller monitors the voltage and temperature of the energy storage element and wirelessly communicates this information on demand to an external system controller which also has a wireless transmitter to receive and send data. Using the data sent from individual cells as input to a program which is resident in the system controller, the system controller determines the state-of-charge and state-of-health of the energy storage system and transmits this information to an indicator. The system controller also controls the voltage equalization among the members of the energy storage system. Voltage equalization is performed by well known conventional means.

The electrically active part of the energy storage element is a pouch cell, either a lithium battery cell or a supercapacitor cell. Pouch cells are well known to those trained in the art and used in a variety of applications, among others in electric cars built by Nissan. The invention calls for the pouch cell to be completely embedded and sealed in a low density plastic resin or plastic housing such that only the terminals of the cells are exposed. The resulting structure of the energy storage element is shaped like a ceramic floor tile, i.e. its width and length are much larger than its height. These energy storage elements are therefore subsequently referred to as energy tiles. The energy tiles of an energy storage system are identical in size and construction. Plus and minus poles of the energy tile are exposed and situated at opposite small sides of the energy tile. The terminals are freely accessible by the opposite terminals of neighboring energy tiles such that cell strings can be produced by arranging energy tiles in such a manner that the plus terminal of the first energy tile touches the minus terminal of the following energy tile. The number of energy tiles in a string determines the string voltage. Energy tiles allow the efficient packing in both single and stacked layers of energy tile strings. Stacked means here that strings of tiles are stacked on top of each other such that the top of the first energy tile string is attached to the bottom of the next energy tile string. An energy tile can be a battery or supercapacitor cell. Energy tile strings are connected in parallel by metal conductors which connect terminals of energy tile strings which have the same polarity and voltage.

In a typical application, the energy tile strings of an energy storage system are connected in parallel to cover a wide variety of surface areas. The resulting pattern is similar in appearance to a surface covered by ceramic tiles. The string length determines the voltage while the number of parallel connections to other strings determines the amount of available current. Only energy tile strings of equal length can be connected in parallel. Depending on the number of energy storage elements in each string and the way in which they are connected with each other, energy tiles can form energy storage systems of various sizes and voltages.

The preferred fastening method to the surface to which the energy tiles are attached is by hook and loop fasteners, generally known by the brand name “Velcro”. The fabric on which the fasteners reside are glued to the energy tile and have their counterpart glued to the surface to which the energy tile is attached. In case of stacked energy tile strings, the top of the energy tiles onto which the overlaying next energy tile string is attached, has hook and loop fasteners attached to their top as well as to their bottoms. The electric connections between adjacent energy tiles are flexible, such that neighboring tiles can tilt relative to each other. To this end connectors which are specific to this invention are disclosed and are part of this invention.

The connectors press the conducting metal foils of two neighboring energy tile terminals having opposite electric polarity together in such a way that the energy tiles can be tilted without losing electrical contact to each other. For low and intermediate currents one type of connector subject to this invention uses the force of magnets to press the current conducting foils of the opposite electric terminals of adjacent energy tiles together so that even while tilted the energy tiles remain in electrical contact by virtue of the magnetic force. This type of connector is subsequently called “magnetic connector”. The magnetic connector consists of two parts, each consisting of a strong permanent cylindrical magnet with a round or prismatic cross section around which an electrically conducting metal foil such as aluminum, copper, or nickel foil is wrapped. One part of the connector is connected to the positive terminal of the energy tile; the other part of the connector is connected to the negative terminal of the adjacent energy tile. To generate the correct connecting force, the magnets of each connector must be consistently oriented to match the polarity of the electrical contact in such a way that only opposite electrical polarities are attracted by opposite magnetic north/south polarities. In this way, the energy tiles can only attract an electric series connection to a directly adjacent tile. To create an electric parallel connection with another series group, an additional magnetic contactor with appropriate magnetic polarity is used for the parallel connection. With the electrically conducting metal foils around the magnets squeezed in between the two attracting magnets, the connecting force is twice the force generated by each magnet alone and sufficient to provide a strong contact between the electric conductors of each part of the magnetic connector, even if the energy tiles are tilted relative to each other.

The contact area of the magnetic connectors is limited to narrow strips along the length of the magnets resulting from the contact area of two cylinders. High currents passing through the magnetic connector may heat up the connector which, as a consequence of the heat, will lose some of the strength of the magnetic force. Therefore, for high currents an alternative connector design is used. Instead of wrapping the metal foil connected to the terminals of the energy tile around magnets, the metal foils are bent upwards by ninety degrees, pointing in a direction of ninety degrees to the top surface of the energy tile, and a clamp is used to hold the two pieces of metal foils of adjacent energy tiles together by mechanical force. The flexibility of the metal foils permits to tilt the energy tiles against each other while providing a reliable electrical connection. Preferred clamps are steel clamps similar to those used to hold paper stacks together. They are electrically insulated by a non-conducting plastic coating. Alternatively, two magnetic platelets are oriented such that they attract each other and are positioned in a manner that they squeeze the two 90 degrees bent metal foils of adjacent energy tile terminals together. The resulting much larger contact area allows for much larger currents to pass through the connection without causing a heat-up of the magnetic platelet.

The flexibility of the magnetic connector and the clamp connector allows the energy tiles to align themselves along a curved or flexible surface. Therefore the surface can also be the fabric of a tent, for example, a military tent. The orientation of the surfaces to which the energy tiles are attached may be horizontal, vertical, or oblique, and solid or flexible. One significant property of this invention is that nonfunctional individual energy tiles can easily be lifted out of the energy storage system and replaced by a working one at the same location without having to disassemble the energy storage system. In case a magnetic connector is used for connecting the energy tiles, the broken energy tile is lifted from the energy storage system by squeezing a screw driver underneath the energy tile to pry it from the hook and loop fasteners and plugging a new energy tile into the space left by the removed energy tile. If the energy tiles are connected by mechanical or magnetic clamps, the clamp is removed first.

Typical candidates for the installation of energy tile based energy storage systems are either internal or external wall or roof surfaces of buildings and similar structures such as the backside of solar panels and internal or external vehicle surfaces. The energy storage system will cover a surface like ceramic tiles and can be as large as the available surface will allow. The installed total voltage of different energy systems depends on the length of the energy tile strings, all of which must have the same length within the same energy storage system but will vary from system to system by increments defined by the cell voltage of an individual energy tile.

### BRIEF DESCRIPTION OF THE DRAWINGS

The advantages and features of the present invention will become better understood with reference to the following detailed description and claims when taken in conjunction with the accompanying drawings in which like elements are identified with like symbols and in which:

FIG. 1 is a block Diagram of the principal components of an energy tile system.

FIG. 2 illustrates a pouch cell with the electrically conducting foil of the plus and minus terminal positioned at opposite ends of the pouch and a cut-out of the electrically insulated pouch material to indicate the electrode package inside the pouch.

FIG. 3 illustrates the folded foil connection attached to the terminals of the energy tile in case the terminals exit the pouch on the same side of the pouch so that the termination of each terminal is positioned at directly opposite ends of the pouch.

FIG. 4 illustrates an energy tile string of two tiles with cut-outs to indicate the electric connection of the two adjacent energy tiles by a magnetic connector as well as the connecting cable to an external charger or load.

FIG. 5 is a partial view of an energy tile string with mechanical and magnetic clamps holding the terminal foils together.

FIG. 6 is the illustration of part of an energy storage system consisting of energy tiles attached with hook and loop fasteners to a vertical wall.

FIG. 7 illustrates an energy storage system consisting of four strings of four energy tiles each connected in parallel to each other by two rods.

FIG. 8 illustrates removal or installation of an individual energy tile in the middle of an energy tile array.

FIG. 9 illustrates various ways an energy tile string can be stacked or curved to best fit a variety of environments.

### DETAILED DESCRIPTION OF THE INVENTION

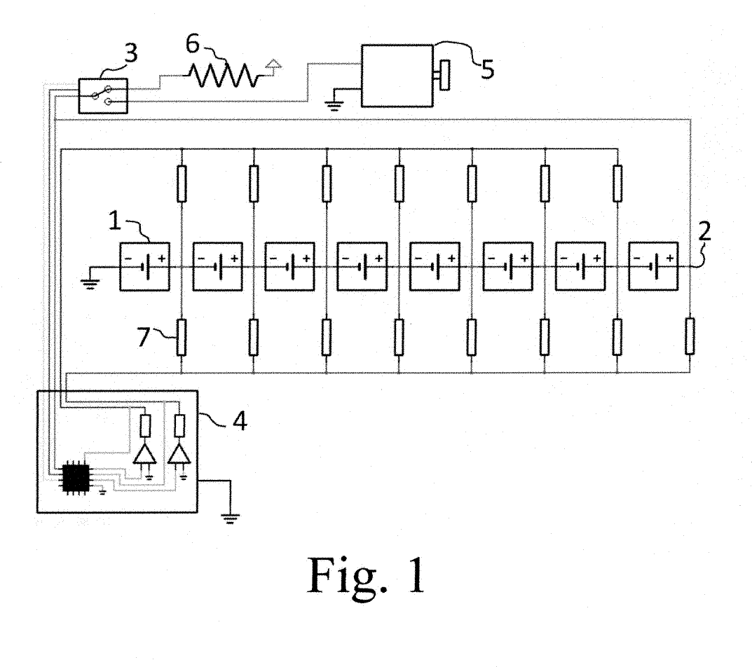

The present invention is depicted in FIG. 1 through 9. However, the invention is not limited to the specifically described and illustrated embodiments. A person skilled in the art will appreciate that many other embodiments of the invention are possible without deviating from the basic concept of this invention.

The terms “a” and “an” as used herein do not denote a limitation of quantity, but rather denote the presence of at least one of the referenced items.

FIG. 1 illustrates by a block diagram the principal components of an energy tile system. In this example the energy is stored in a representative string of eight energy tiles 1 connected in series. The plus terminal 2 of the energy tile string is connected to a charger 5 or load 6 by way of a double pole contactor 3. The status of the connection depends on the state-of-charge of the energy storage system. The system controller 4 determines the state-of-charge of the energy storage system from measurements of charge/discharge current measurements and from voltage and temperature measurements of individual energy tiles and, based on the state-of-charge, controls the contactor 3 to connect the energy storage system to either the charger 5 or to the load 6. The system controller 4 also controls the electronic gates 7 of the voltage equalization system.

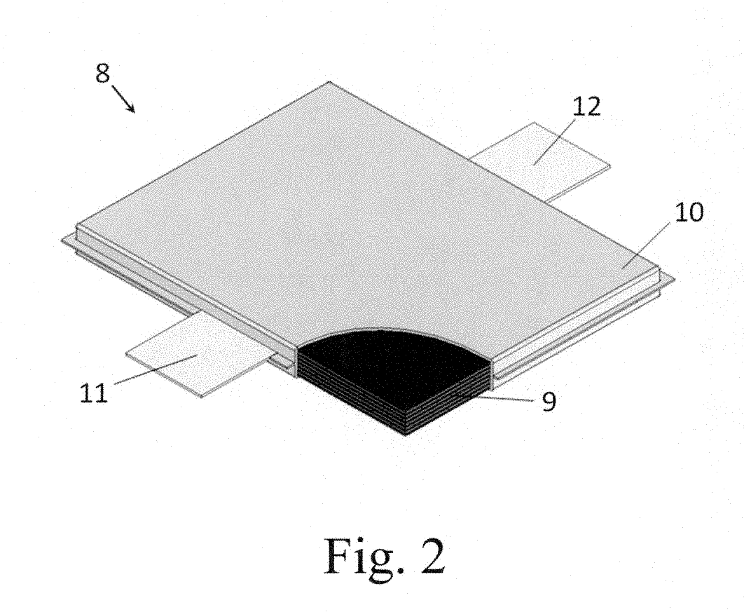

FIG. 2 illustrates a prior art pouch cell 8 which is the energy storing part of the energy tile. The pouch cell can be either a lithium battery cell or a supercapacitor cell. It consists of a stack 9 of electrodes and separators which is surrounded by the walls of a pouch 10 made of heavy aluminum foil such that only the plus 11 and minus 12 foil terminals of the electrodes are sticking out. The aluminum foil of the pouch enclosure is coated on both sides with a non-conducting polymer. The pouch cell 8 contains immobilized electrolyte and is completely sealed.

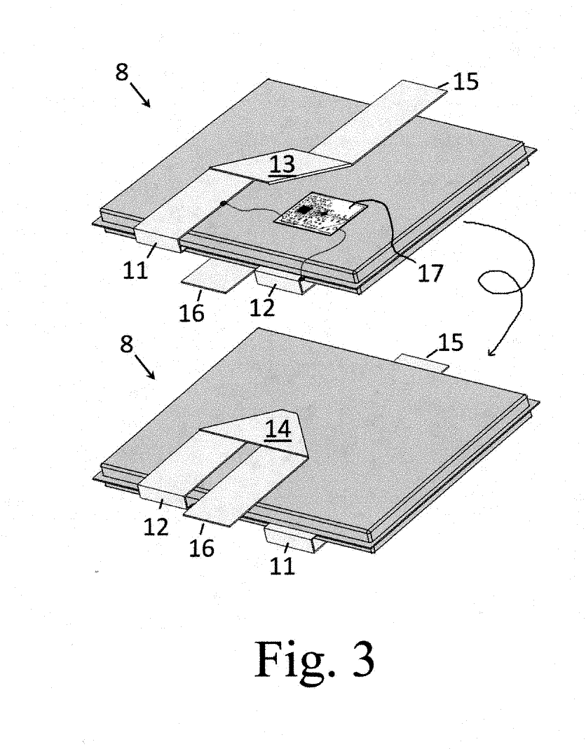

FIG. 3 illustrates the case where the pouch cell 8 is manufactured such that the foil terminals 11 and 12 exit the pouch cell 8 on the same side. In order to position them on opposite sides, an electrically conducting foil strip is welded to each of the foil terminals and folded, one strip 13 over the top and the other strip 14 over the bottom of the pouch cell 8, such that their ends 15 and 16 exit the pouch area on opposite sides. A microprocessor based monitor 17 is attached to the outside of the pouch and part of each energy tile and communicates by radio frequency (RF) with the system controller 4. The microprocessor based monitor 17 tracks the voltage and temperature of the energy tile and communicates this information by RF on demand by the system controller 4 to the system controller 4. The antenna of the microprocessor based monitor 17 in the energy tile is an integrated part of the printed circuit board of the monitor 17.

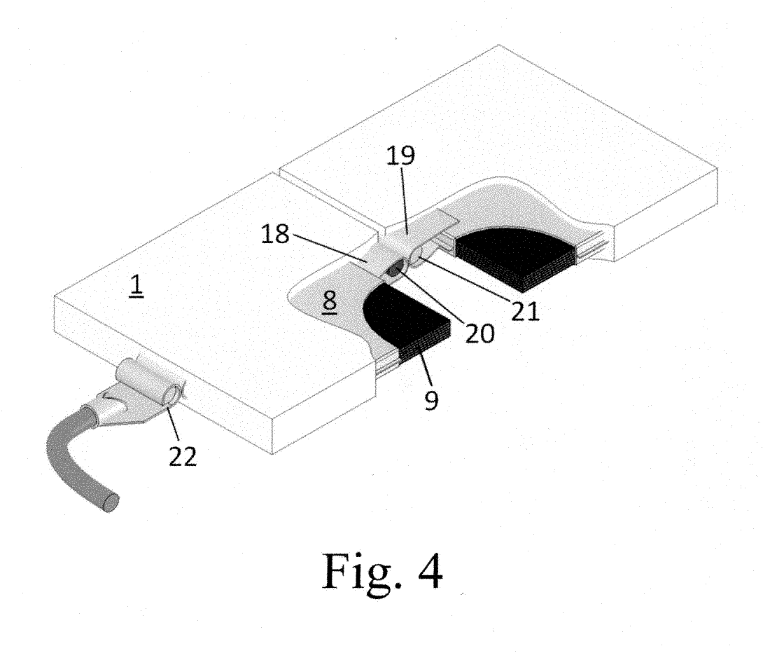

FIG. 4 illustrates two neighboring energy tiles 1 electrically connected by a magnetic connector which connects the negative terminal of an energy tile 1 with the positive terminal of the adjacent tile. The terminal foils 11 and 12 from FIG. 2 protruding from the pouch cells 8 are reinforced in FIG. 4 by thicker metal foils 18 and 19. They are welded to the terminals foils 11 and 12 from FIG. 2 and wrapped around cylindrical magnets 20 and 21 which are oriented such that they attract each other and squeeze the foil material 18 and 19 of each energy tile 1 together in such a way that an electric current can flow from one energy tile to the other. Thus, the two connected tiles build an energy tile string with an electric series connection. One end of the energy tile string is electrically negative, the other end is electrically positive. The magnetic connector 22 is similar in construction to the magnetic connection between the energy tiles and connects to an electric cable which may be connected to a charger or load.

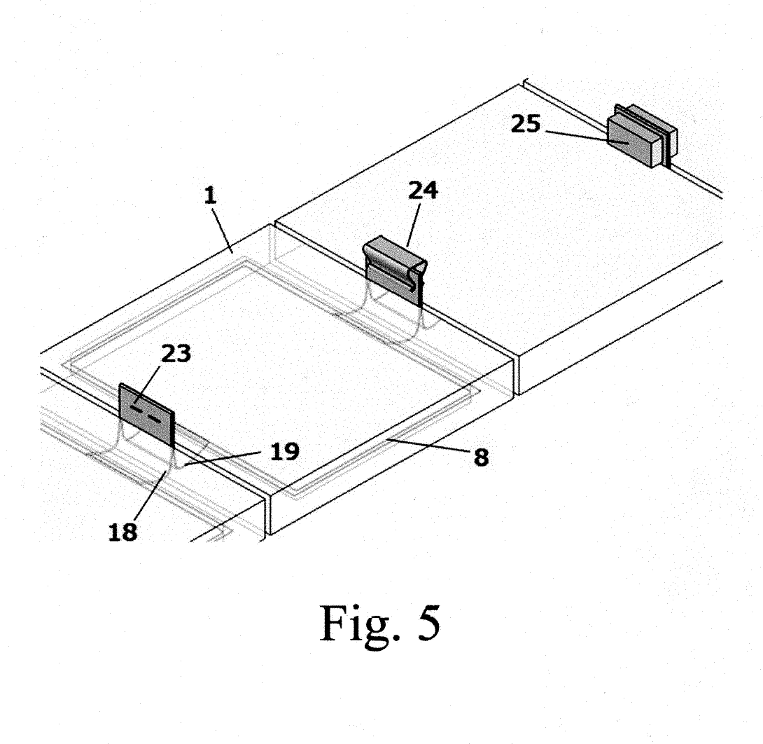

FIG. 5 illustrates a section of an energy tile string with mechanical 24 and magnetic 25 clamp connectors. The foil material 18 and 19, instead of being wrapped around magnets is bent upward by 90 degrees and squeezed together 23 by a mechanical clamp 24 or two magnetic platelets 25 which are oriented such that they attract each other while squeezing the foils 18 and 19 in between the magnetic platelets 25 together.

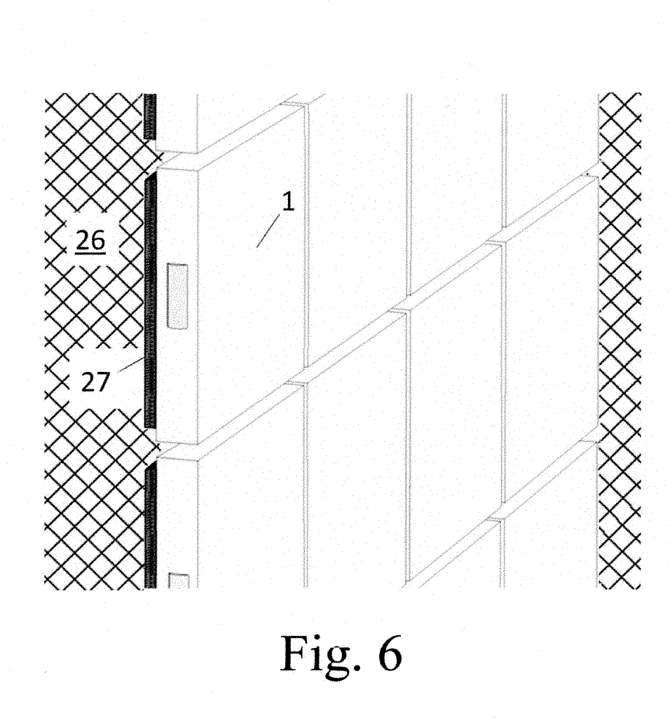

FIG. 6 illustrates how energy tiles 1 are fastened to a vertical wall 26 by hook and loop fasteners 27, commonly known by the trade name “Velcro.” These interlocking fasteners 27 consist of two parts. One part of the fasteners is glued to the bottom of each energy tile and the counterpart is glued to the wall. The installation of the fasteners 27 is such that electrical contact between the energy tiles of a string is maintained after the installation.

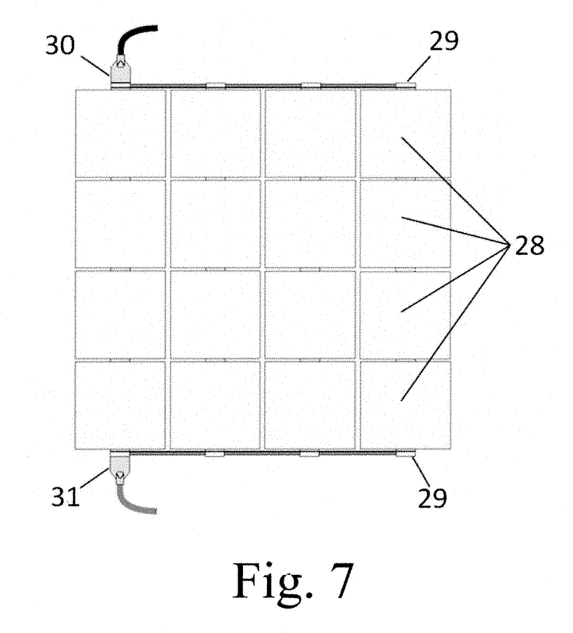

FIG. 7 illustrates a four by four panel of energy tiles. Strings 28 of four energy tiles are connected in parallel by metal rods 29, connecting the negative 30 and positive 31 terminals of the energy tile strings together.

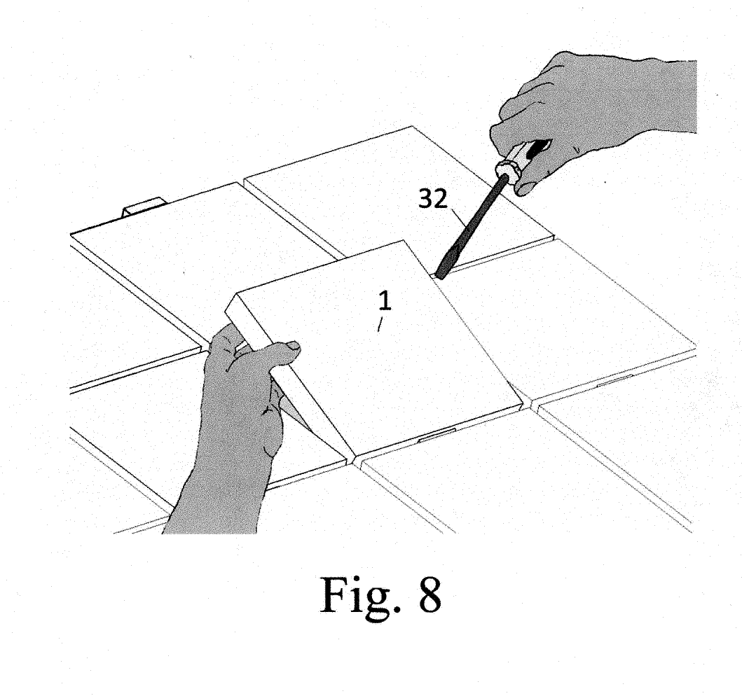

FIG. 8 depicts how an individual energy tile 1 can be quickly removed and replaced from an energy tile array by simple mechanical leverage with a flat wedge such as a screw driver 32.

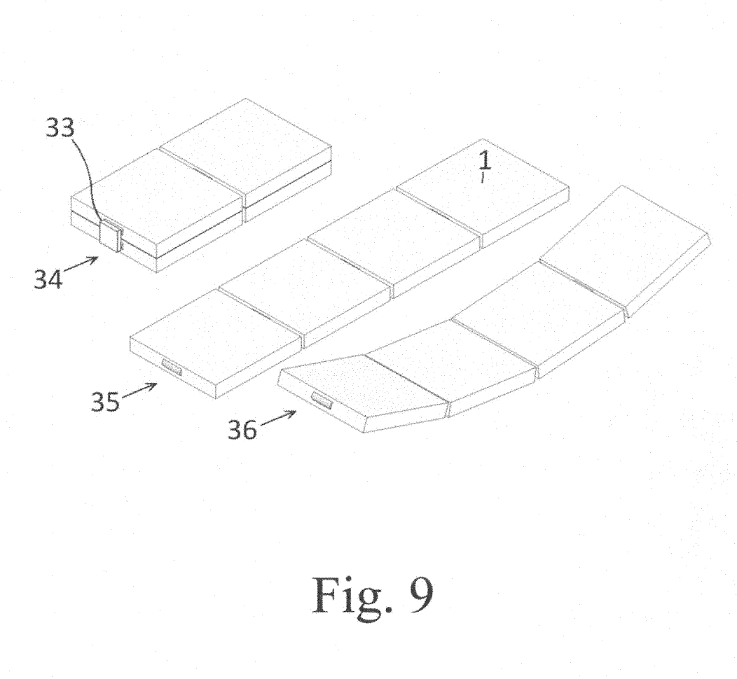

FIG. 9 gives examples of how an energy tile series-connected string 33 can alternatively be stacked 34 by using a magnetic connector 35, or curved 36 to match a non-planar surface. This versatility of arrangement is made possible by the flexible nature of the magnetic connection described in FIG. 4 and likewise by the welding and clamping methods described in FIG. 5.

What is claimed:

1. An energy storage system comprising:
Energy storage elements, either lithium batteries or supercapacitors having identical voltage rating, that are mounted on free 2- or 3-dimensional surfaces such as internal or external walls or roof surfaces of buildings and similar structures such as the backside of solar panels and internal or external vehicle surfaces.
An electric current source operatively connected to said energy storage elements.
A useful electric load operatively connected to said energy storage elements.
A two-pole contactor operatively connected to the electric current source and the said load.
A microprocessor based system controller and RF transmitter operatively connected to said two-pole contactor and in RF communication with each of the energy storage elements.

2. The energy storage system according to claim 1, wherein the individual energy storage elements, also referred to as “energy tiles”, are completely encased and sealed in plastic shaped like ceramic tiles, i.e. their height is much smaller than their width and length, and wherein the size and shape of each energy tile is identical.

3. The energy storage system according to claim 1, wherein the individual energy storage elements are mounted on said surfaces in a pattern similar to ceramic tiles covering a surface.

4. The energy storage system according to claim 1, wherein the individual energy storage elements have the plus and minus terminal on opposite small sides of the energy tile.

5. The energy storage system according to claim 1, wherein the individual energy tiles are fastened to the said surface according to claim 1 by hook and loop fasteners, sometimes referred to by the brand name “Velcro.”

6. The energy storage system according to claim 1, wherein the individual energy storage elements are electrically connected in serial strings of equal length sitting side by side, covering a surface. These strings are connected in parallel, tying all positive terminals and all negative terminals together by electrically conducting rods.

7. The energy storage system according to claim 1, wherein the individual energy tiles are electrically connected in such a way that they can be tilted relative to each other without losing electrical contact with each other.

8. The energy storage system according to claim 1, wherein the individual energy tiles can be lifted out of the energy storage system and replaced without disturbing the remaining energy tiles.

9. An electricity-conducting connection method based on the magnetic force of two attracting magnets which squeeze the metal foils connected to the terminals of an energy tile together such that electric current can flow from one energy tile to the next energy tile.

10. An electricity-conducting connection method based on the mechanical force of a spring operated clamp squeezing the metal foils connected to the terminals of an energy tile together such that electric current can flow from one energy tile to the next energy tile.

11. A magnetic connector where the metal foils connected to the energy tile terminals are wrapped around cylindrical magnets having either a round or prismatic cross section and are partially embedded in the plastic body of the energy tile.

12. A microprocessor-based voltage and temperature monitor embedded in the plastic body of each energy tile having an integrated RF transmitter and a printed antenna on the printed circuit board
